(19) United States
(12) Patent Application Publication
(10) Pub. No.: US 2026/0011627 A1
(43) Pub. Date: Jan. 8, 2026

(54) SEMICONDUCTOR DEVICE WITH A DIELECTRIC SPACER AND METHOD OF MANUFACTURING

(71) Applicant: Infineon Technologies Austria AG, Villach (AT)

(72) Inventors: Bok Keun Song, Seoul (KR); Byoung Ho Choo, Bucheon-si (KR); Jeong Su Cho, Cheonan-si (KR); Joon Seo Son, Seoul (KR); Man Kyo Jong, Bucheon-si (KR); Sung Mo Young, Seoul (KR)

(21) Appl. No.: 19/250,855

(22) Filed: Jun. 26, 2025

(30) Foreign Application Priority Data
Jul. 8, 2024 (DE) 102024206385.1

(51) Int. Cl. H01L 23/495; H01L 21/48; H01L 23/32; H01L 23/367

(52) U.S. Cl. CPC H01L 23/49558; H01L 21/4842; H01L 23/32; H01L 23/3675

(57) ABSTRACT

A semiconductor device includes a package body having a topside in a first plane and a bottom side in a second plane parallel to the first plane. At least one lead protruding out of the package body has a first portion in a plane parallel to the first plane and a second portion being bent away from the first plane towards the second plane. A cavity is positioned between the at least one lead and a feature of the semiconductor device. A removable dielectric spacer is configured to be positioned in the cavity between the at least one lead and the feature. The dielectric spacer is longer than the at least one lead.

### TECHNICAL FIELD

The present disclosure relates to a semiconductor device comprising a package body and a dielectric spacer. The present disclosure further relates to a method for manufacturing the aforementioned semiconductor device.

### BACKGROUND

Mounting a packaged chip to another device, e.g. a heatsink for cooling, may require a safety distance between a lead of the packaged chip and the attached device, especially if the attached device is of an electrically conductive material, e.g. Aluminum.

To enhance the safety distance, which may both be a clearance distance and a creepage distance, several approaches have been made. For example, using a convex, balcony-like heatsink has been proposed to move the conductive surface of the heatsink further away from conductive parts of the semiconductor device. Further, to increase the creepage distance, it has been proposed to add grooves between leads on a package outline.

Hereafter, the creepage distance is defined as the distance of a creepage current along a surface, wherein the clearance distance is a required distance between two conductors through air.

A major drawback of the above proposals is that a creepage distance can be increased but the clearance distance cannot.

It is therefore an intention of the present disclosure to provide a semiconductor device with increased creepage and clearance distance.

### SUMMARY

According to a first aspect of the present disclosure a semiconductor device is provided, the semiconductor device comprising a package body having a topside in a first plane and a bottom side in a second plane parallel to the first plane, at least one first lead protruding out of the package body, the lead comprising a first portion in a plane parallel to the first plane, and a second portion being bent away from the first plane towards the second plane, a cavity positioned between the at least one lead and a feature of the semiconductor device, and a removable dielectric spacer configured to be positioned in the cavity between the at least one first lead and the feature, wherein the dielectric spacer is longer than the lead.

The package body may consist of or comprise a mold compound. The package body may be a rectangular body comprising a flat top side and flat bottom side, which is parallel thereto. The package body may generally consist of nonconductive material.

The nonconductive material can also be a polymer material, a polyimide material, a thermoplast material, a silicone material, a ceramic material, and a glass material. The nonconductive material may also comprise any of the above-mentioned materials and further include filler materials embedded therein like, for example, thermally conductive increments like thermally conductive particles like, for example, made of AIO, BNi, AlNi, SiN, diamond, any other thermally conductive particles, or non-thermal conductive fillers, e.g. SiO, SiO2, glass etc.

However, conductive features may be arranged at outer surfaces of the package body or protrude out of the package body.

As an example, at least one first lead may protrude out of the package body. The first lead may connect to electrically conductive parts of a semiconductor chip, which may be encapsulated inside the package body. The first portion of the lead protrudes outside the package body at a peripheral sidewall and may be substantially parallel to the first plane. The second portion of the lead is bent downwards toward the second plane and may form a portion that connects with second devices.

The second portion of the lead may be bent away from the first plane to form a foot like connector for connecting the semiconductor device to a second device, e.g. a PCB or another semiconductor device in a device stack.

The package body comprises a cavity or may be structured by a plurality of cavities. The cavity may be arranged at a peripheral sidewall or may form an edge portion of the topside of the package body. The cavity may be spaced apart from the first plane. The cavity may also be formed between the first plane and the surface of the package body at the edge portion. Alternatively, the cavity may be a recess, a bore or a slot in the peripheral sidewall of the package body. The peripheral sidewall may be substantially vertical.

The cavity may be arranged between a first lead protruding out of the package body and a further feature, which may be electrically conductive. Thereby, for example, a distance along a surface between the lead which protrudes out of the package body at a vertical side of the package body and the feature is enlarged. This results in an enlarged creepage distance along the surface of the cavity. For example, the feature may be a heatsink.

An air space between the first lead and the feature resulting from the cavity may be filled by the dielectric spacer. The dielectric spacer may be fixedly attached to a surface of the package body and may fill the cavity. By filling the airspace with the dielectric spacer, the air between the lead and the feature is replaced by an isolation material of the dielectric spacer. This increases the clearance distance between the lead and the feature, because the clearance distance is formed from the border of the cavity and dielectric spacer to the first portion of the lead through the micro gap between them. Moreover, the dielectric spacer may cover the first portion of the lead and fill a space between the first portion of the lead and the first plane.

The dielectric spacer extends along the second portion of the lead wherein the dielectric spacer may at least extend to the second plane and fill a space between the second portion of the lead and the first plane. Thereby, the dielectric spacer builds a barrier between the first plane and the second portion of the lead and thereby increases a safety distance between the lead and the first plane in which a conductive feature may be arranged. By inserting an isolation material into the space, the clearance distance is increased.

The spacer may be longer than the lead. Especially, both a vertical and a lateral extension of the spacer with respect to the lead may be such that both the first portion of the lead and the second portion of the lead is shorter than the dielectric spacer along its respective longitudinal extension. Thereby, the dielectric spacer may protrude at least in part into the cavity at the package body, or into further cavities at a second device, as will be further detailed below.

By letting the dielectric spacer protrude into the cavity, at least in part, a direct line of sight between, for example, the lead and an adjacent conductive feature is interrupted. That is, the clearance distance is interrupted by the dielectric spacer. The further the dielectric spacer protrudes into the cavity, the more a clearance distance equals the creepage distance.

By increasing creepage and clearance distance, by the dielectric spacer, a reduction of the formfactor is possible. In turn, if a substrate size is kept constant, a power density can be increased.

By virtue of this first aspect of the disclosure, the influence of a pollution of an environment on a dielectric strength of the semiconductor device may be decreased. In turn, the semiconductor device according to the first aspect may be used in environments having a higher pollution degree, i.e. in more rugged environments.

In one embodiment, the feature may be a second lead. In this embodiment the dielectric spacer may be arranged between two neighbouring leads protruding out of a peripheral sidewall of the package body. The removable dielectric spacer may hence be attached such that a portion of the dielectric spacer is arranged between the leads and protrudes into the cavity. In this embodiment the cavity may be arranged at an outer surface of the package body between the first portions of the leads.

In an embodiment, the dielectric spacer may contact a bottom surface of the cavity. Also in this embodiment, a respective portion of the dielectric spacer is longer than the first portion of the lead. The dielectric spacer may extend into the cavity and contact the surface of the cavity. Thereby a clearance distance between two neighbouring conductive parts, for example two leads, which are separated by the cavity, is made equal to the creepage distance, which is defined along the surface of the cavity from one lead to another. If more than one lead is present, the dielectric spacer may also fully occupy an air space between two neighboring leads which results in an increased clearance distance. The clearance distance between two leads filled by the dielectric spacer becomes the same as the creepage distance. This enables to reduce the distance between neighboring leads, which may result in a reduction of formfactor of the semiconductor device. As the clearance distance is also enhanced, devices having a smaller formfactor, i.e. a closer distance between leads, would not have to be tested on their safety before use by a customer of the device.

In an embodiment, the dielectric spacer extends along the second portion of the first lead to encapsulate at least an outer side of the first lead and to fill a clearance distance between neighboring first and second leads.

The dielectric spacer may comprise a vertical outer face having a side surface which is in a plane vertical to the second and first plane. The vertical outer face may be the part that at least partially covers the outer side of the second portion of the leads. The second portion of the leads may form a sharp angle with the vertical outer face of the dielectric spacer. Hence, the dielectric spacer may extent vertically from the second portion of the leads towards the second plane and form a vertical outer face of the semiconductor device. The vertical outer face of the dielectric spacer may form a right angle with the second plane and/or the first plane. The dielectric spacer may only cover a part of the second portion of the leads, wherein a subsequent part is exposed. Both the creepage distance and the clearance distance between the non-covered, exposed part of the second portion of the lead and the first plane equal the vertical distance along the vertical side face of the dielectric spacer. Hence, by forming such a vertical side face of the dielectric spacer, the safe distance can be adapted as required and is always at least in the range of the distance of the vertical outer face of the dielectric spacer.

In one embodiment the feature is a heatsink, wherein the heatsink comprises a flat bottom surface and is attached to the topside of the package body and protrudes horizontally past a peripheral sidewall of the package body.

The heatsink may be of an electrically and thermally conductive material and may be attached with a flat side to the topside of the package body. The flat side (i.e. bottom side) of the heatsink is located in the first plane. The cavity may be a step-like portion at the topside of the package body. By filling this cavity with the dielectric spacer, the clearance distance between the package body and the heatsink is eliminated. If the heatsink is attached in the first plane of the package body, the safety distance from a lead to a bottom side of the heatsink is increased. Consequently, a heatsink having a flat bottom side may be used. Consequently, design and manufacture of the heatsink is simplified and yields more flexibility in the mechanical and thermal design. For example, it may be possible to optimize the fin design regardless of the direction of the package body in relation to a PCB.

In one embodiment an outer edge of the heatsink protrudes past an outer edge of the dielectric spacer; and/or wherein the dielectric spacer does not pass the outer edge of the heatsink.

A distance between the second portion of the leads and the heatsink, which may be seen as a conductive material, is filled with the dielectric spacer. In this case the remaining clearance distance between the second portion of the lead and the heatsink may be a distance between a lower portion of the second portion of the lead which may not be covered by the dielectric spacer and the bottom surface of the heatsink. As the clearance distance is a free air distance between two or more electrically conductive materials, the clearance distance between the second portion of the lead and the heatsink may be enlarged by covering the second portion of the lead with the dielectric spacer and thus enlarging a free air length between uncovered portions of conductive material, i.e. the lead and the heatsink. The more of the second portion of the lead is covered by the dielectric spacer, i.e. the more the dielectric spacer extends downward along the lead, away from the first plane of the package body, the more of the lead is covered by the spacer and the larger the free air distance between exposed, non-covered parts of the lead and the heat sink becomes. To increase said clearance distance even further, the spacer should not pass the edge of the heatsink, i.e. the spacer should not be bigger than the heatsink but extend vertically along the lead.

In one embodiment, the dielectric spacer may be a plastic cover, wherein the plastic cover is an integral part and wherein the plastic cover is configured to be removably attachable to the package body by way of a screw or a clip or a latch.

A plastic cover may be particularly easy to manufacture. The plastic cover may be molded or extruded or printed separately to form a single one-piece part, which is obtained in only one process step. Moreover, the plastic cover can then be assembled with the molded package body after trim/form by a pick and place process. This makes the assembly easy to be processed.

The dielectric spacer may be removably attached to the package body by any known mechanical means, however preferably by way of a screw or a clip or a latch.

In one embodiment the dielectric spacer acts as a standoff including the second portion of the leads. In this case the dielectric spacer works as a spacer to control the standoff height of the package body with respect to a second device (e.g. a PCB) to which the semiconductor device may be attached.

The stand-off controls the distance between a package body and a PCB when a semiconductor is soldered on a PCB. By the dimensions of the dielectric spacer, i.e. the extent that the dielectric spacer covers the second portion of the leads, it is possible to define/control the standoff height and to enable the semiconductor device to be robustly attached to the PCB. As the clearance distance is enhanced by covering the second portions of the lead, the standoff height may also be reduced. The dielectric material of the dielectric spacer acts as the standoff. A reduction of the standoff height usually requires changes in leadframe design. By virtue of the dielectric spacer, the standoff height can be easily adjusted with little effort, since the easy-to-change dielectric material can be easily varied.

In one embodiment the standoff comprises a protrusion which protrudes into a slot of a printed circuit board, PCB, to enhance a creepage distance between two leads on the PCB. Particularly, the protrusion may have a height of about a thickness of the PCB.

This increases both clearance and creepage distance along the top side of the PCB (at the bottom side, usually conformal coating is used). If the protrusion of the spacer goes through the PCB, the clearance and creepage distance between leads may be increased. When the dielectric spacer can get extended into the PCB, both the clearance and creepage between leads may be enlarged.

In one embodiment, the slot is a through-hole, through which the protrusion protrudes, and wherein a length of the protrusion is at least a length of the second portion of the leads protruding through the second device.

In this embodiment the leads are protruding trough the PCB such that the second portion of the leads protrude past the backside of the PCB. Hence, adjustment of creepage and clearance distance at the backside of the PCB may be required. To enhance both clearance distance and creepage distance at the backside of the PCB between two neighbouring leads protruding out of the PCB the dielectric spacer may have a protrusion, as detailed above. However, the protrusion may reach trough the slot in the PCB and be as long as the leads. Thereby, a dielectric barrier may be installed between the neighbouring leads at the backside of the PCB. Alternatively, conformal coating may be used on the backside of the PCB eliminating both the creepage distance and the clearance distance.

According to a second aspect of the present disclosure there is provided a method for manufacturing a semiconductor device, the method comprising providing a package body having a topside in a first plane and a bottom side in second plane parallel to the first plane; providing at least one lead protruding out of the package body, the providing comprising: arranging a first portion of the lead in a plane parallel to the first plane, and bending a second portion of the lead away from the first plane towards the second plane; providing a cavity between the at least one lead and a feature of the semiconductor device; and positioning a removable dielectric spacer in the cavity between the at least one first lead and the feature, wherein the dielectric spacer is longer than the lead.

All embodiments described in relation to the first aspect, may be combined, in any arbitrary sequence, with the second aspect of the disclosure.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1 illustrates an example of a safety distance between two leads.

FIG. 2 shows a semiconductor device.

FIGS. 3a and 3b show an exemplary embodiment of the semiconductor device of FIG. 2.

FIG. 4 shows a further embodiment of the first aspect of the disclosure.

FIG. 5 shows several embodiments of the semiconductor device in a variety of use cases with a heatsink.

FIG. 6 illustrates a device according to the first aspect of the disclosure having different mechanical attachment possibilities.

FIG. 7 illustrates a device according to the first aspect of the disclosure having a clip.

FIG. 8 illustrates a detail of a device according to the first aspect of the disclosure.

FIG. 9 is a process chart of the second aspect of the disclosure.

### DETAILED DESCRIPTION

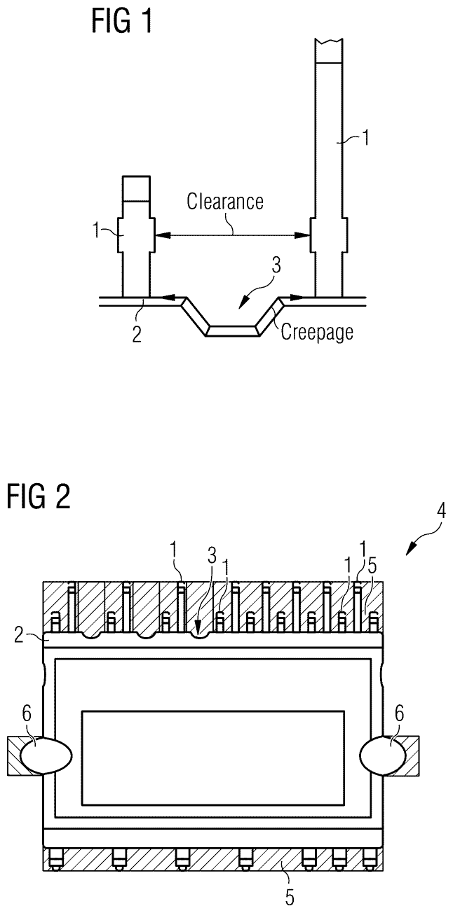

FIG. 1 illustrates an example of a safety distance between two leads 1. The safety distance comprises both a creepage distance and a clearance distance. In FIG. 1, the creepage distance is the distance between two neighboring leads 1 along a surface of a package body 2 from which the leads 1 protrude. As the creepage distance is a distance along the surface, a slot 3 increases the creepage distance from lead 1 to lead 1. The clearance distance, however, is the minimal distance between two current-carrying conductors through air. Hence the clearance distance is unaffected by slots 3 in the package body 2. One way of increasing the clearance distance is to space neighboring leads 1 sufficiently apart from one another. However, this can lead to an undesirable increase in the package size.

FIG. 2 shows an exemplary embodiment of a semiconductor device 4 from a topside view. The semiconductor device 4 includes a dielectric spacer 5. The dielectric spacer 5 includes portions which are positioned between the leads 1. As described with respect to FIG. 1, slots 3 are provided in the vertical sides of the package body 2 to increase the creepage distance along the surface between the neighboring leads 1. The portions of the dielectric spacer 5 are inserted into the slots 3, increasing the clearance distance so that it becomes equal to the creepage distance. Generally, inserting an isolating material between two conductors has the effect that the clearance distance is increased, because a free minimal length between the conductors is interrupted. In the present case, the new minimal free length from one lead 1 to another is the distance around the inserted dielectric spacer 5. In case the dielectric spacer 5 is inserted between two leads and extends to the surface of the slot 3, the clearance distance equals the creepage distance. The dielectric spacer 5 embeds the package body 5.

Additionally, in the embodiment of FIG. 2, the package body 2 comprises recesses 6 at two opposite sides of the package body 2. The recesses 6 serve as screw holes for fixing the semiconductor device 4 to a substrate. e.g. a PCB (not shown). Recesses 6 may be circular or semicircular and may also form eyes at the outer face at the short sides of the package body 2.

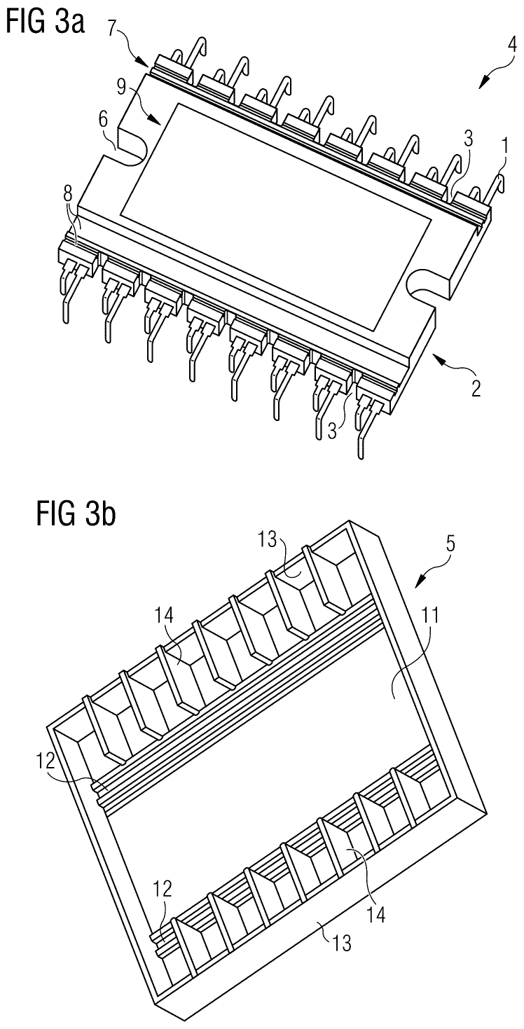

FIGS. 3a and 3b show an exemplary embodiment of the semiconductor device 4 of FIG. 2.

FIG. 3a shows the semiconductor device 4 of FIG. 2 without the dielectric spacer 5. The slots 3 divide the package body 5 in the vicinity of the first portion of the leads 1 into separate finger-like protrusions. An edge portion 7 of the package body 2 is structured by a groove structure 8 comprising several grooves in the first plane 9 of the package body 2. The groove structure 8 at the edge portion 7 may have different shapes and is not necessarily symmetric at opposing sides of the package body 2. The groove structure 8 further increases the creepage distance from the first portion of the lead 1 to a further device 10 (not shown). The groove structure 8 may be interrupted by the slots 3, such that at least one groove of the groove structure 8 is non-continuous through the finger-like protrusions from which the leads 1 protrude. In the embodiment of FIG. 3a the groove structure 8 is only present at the long sides of the package body 2, whereas the shorter end faces of the package body 2 are free of grooves. The groove structure 8 may have a height which is smaller than the package body 2, i.e. an upper surface of the groove structure 8 is spaced away from the first plane 9 of the package body 2.

FIG. 3b shows the dielectric spacer 5 configured to match the exemplary semiconductor device 4 of FIG. 3a. The dielectric spacer 5 is a rectangular frame-like plastic part, which can also be referred to as a plastic cover. The plastic material can be a dielectric mold compound and can be manufactured by molding or injection molding. The dielectric spacer 5 is configured to be removably attached to the package body 2 from a top side. The dielectric spacer 5 comprises an opening 11. In a state in which the dielectric spacer 5 is attached to the package body 2, the opening 11 corresponds to an inner portion of the top side of the package body 2. Thereby, a heatsink or a further device 10 can be attached to the package body 2 and is not hampered by the dielectric spacer 5. The dielectric spacer 5 further comprises first portions 12 configured to be positioned in the grooves of the groove structure 8 of the package body 2.

The first portions 12 are configured to fill the space inside the grooves of the groove structure 8, or they may merely be planar structures or other useful forms serving as an air barrier. The dielectric spacer 5 further comprises second portions 13 configured to be positioned laterally outside of the second portions of leads 1. In FIG. 3b the second portions 13 are shown to be vertical walls, but they may also be structured so as to contact the second portions of the leads 1 along their lengths.

Further, the dielectric spacer 5 comprises third portions 14, which are configured to be positioned between the leads 1 and to positively interlock with the slots 3 between the leads 1 to increase the clearance distance from lead to lead to the creepage distance. In FIG. 3b these third portions 14 take the form of vertical fins, but they may instead be configured to entirely fill the spaces between the leads 1, or to take some other form.

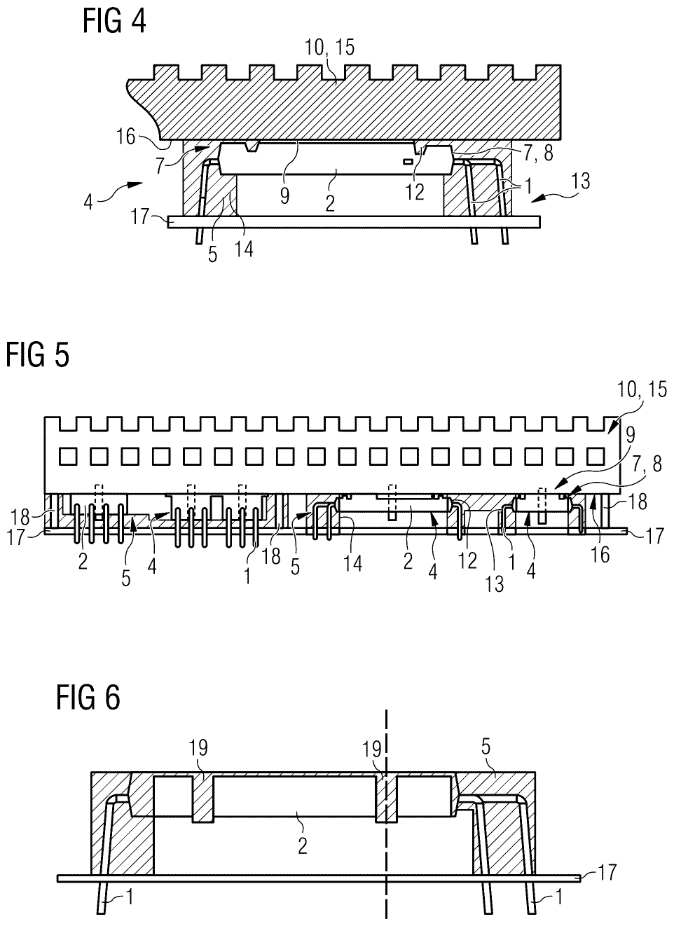

FIG. 4. shows a further embodiment of the first aspect of the disclosure described in FIG. 3. A further device 10 is attached to the semiconductor device 4. The further device 10 is a heatsink 15. The heatsink 15 has a planar bottom side 16 and is attached to the topside of the package body 2. A footprint of the heatsink 15 is larger than a footprint of the semiconductor device 4. Particularly, edges of the heatsink 15 protrude past the second portion of the leads 1 in a lateral direction, wherein the lateral direction is parallel to the first plane 9. In this embodiment, at least the outer face of the second portion of the lead 1 is fully covered by the second portions of dielectric spacer 13. Moreover, edges of the heatsink 15 protrude past an outer face of the dielectric spacer 5. Particularly, a footprint of the heatsink 20 is larger than a footprint of the dielectric spacer 5. In this case the clearance distance between the second portion of the lead 1 and the bottom side 16 of the heatsink 15 is a distance along the outer face of the dielectric spacer 5 to the bottom side 16 of the heatsink 15, i.e. the clearance distance is the distance from a point of the second portion of the lead 1 which is not covered by the dielectric spacer 5, and which is hence an free conductive surface to the conductive bottom side 16 of the heatsink 15 along the outer face of the dielectric spacer 5.

The semiconductor device 4 is attached to a substrate 17, which may be a PCB or the like. The dielectric spacer 5 acts as a standoff spacing the package body 2 apart from the substrate 17. The leads 1 protrude through the substrate 17, as will be further detailed below.

FIG. 5 shows several embodiments of the semiconductor device 4 of FIGS. 3a and 3b in a variety of use cases. For the ease of reference, several different semiconductor devices 4 are connected to one single heatsink 15. Moreover, all of the semiconductor devices 4 are connected to a common PCB 17, which is however only for illustration purposes. At the left side of FIG. 5 devices 4 are devices containing diodes, like a bridge diode or a Power Factor Correction Circuit (PFC) with an IGBT and a diode but are not limited thereto. On the right side of FIG. 5 devices 4 are integrated power modules (IPMs). The heatsink 15 is an earthed heatsink, wherein the electrical connections to ground 18 are located besides the devices 4 forming a frame or pillars to support the heatsink 15. The dielectric spacer 5 acts as a standoff to limit and to control a space between the bottom side of the heatsink 15 and the PCB 17. The second portion of the lead 1 is at least at its outer side fully covered by the isolation material of the dielectric spacer 5.

Semiconductor devices 4 on the left side of FIG. 5 and the semiconductor devices 4 on the right side of FIG. 5 are both Through Hole Devices (THDs), however with different package outline. However, the disclosure is not limited to THDs. The disclosure is also possible with Surface Mount Devices (SMD). THDs and SMDs may also be mixed in the same application. Consequently, the form of the dielectric spacer 5 is adapted to the form of the package body 2. In case of a flat THD, the form of the dielectric spacer 5 is different as in case of the semiconductor device 4 vertical or vertical but bent THD, e.g. a TO-247.

As can be seen, by virtue of the dielectric spacer 5, the heatsink 15 is not a convex part, but has a planar bottom surface 16. Hence, the heatsink 15 can be more easily obtained from multiple heatsink suppliers, which allows a cost down of the heatsink 15 and facilitates easier thermal design of the heatsink. Moreover, the pollution degree PD can be increased (e.g. from PD 2 to PD 3) because the leads 1 are covered and encased and are hence protected from polluted surroundings, e.g. dusty air, in rugged manufacturing environments.

FIG. 6 shows a further embodiment of the package body 2 and the dielectric spacer 5 described in connection with FIGS. 3a and 3b. The dielectric spacer 5 is a plastic cover and is attached to the package body 2 by way of one or more clips 19. The clips 19 are configured to removably attach the plastic cover to the package body 2. Clips 19 may be formed with the other parts of the plastic cover at the same time during the manufacturing process, e.g. during injection molding. Alternatively, the clips 19 may be formed separately from the dielectric spacer 5 and applied after the spacer 5 has been placed on the package body 2. The clips 19 are shown here to be located at the shorter end-faces of the package body 2 and configured to reach under the bottom side of the package body 2 and to form a positively interlocking connection with the package body 2, though of course other clip locations are also possible. For example, clips 19 could be connected to the third fin-like portions 14 so as to extend over the bottom side of the package body 2.

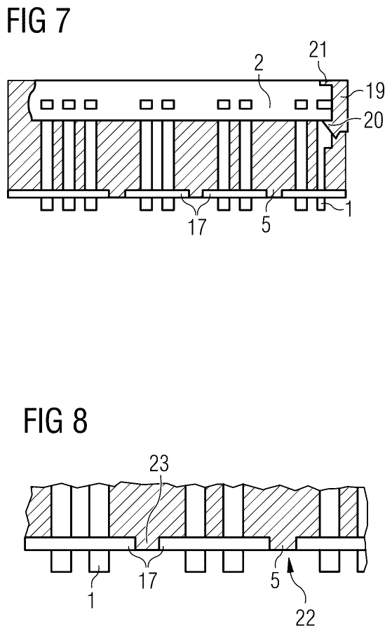

FIG. 7 is s cross sectional view of FIG. 6 through the dashed line. The clip 19 has a lock-in catch 20 which engages positively with the bottom side surface of the package body 2. To better position the plastic cover, the package body 2 may have a step 21 at the topside 6 at the shorter end faces of the package body 5. Step 21 is a recess in the topside of the package body 2 at the outer edge of the shorter end faces of the package body 2. Step 21 may be part of the groove structure 8. The step 21 is also filled by the dielectric spacer 5, wherein the dielectric spacer 5 and the topside are both in the first plane 9. The dielectric spacer 5 fills the step 21. i.e. a space between a surface of the step 21 and the first plane 9, so as to form a uniform planar topside surface.

FIG. 8 shows a further embodiment of the first aspect of the disclosure in which the PCB 17 has an opening 22 in which a part of the dielectric spacer 5 fits in. The dielectric spacer 5 has a protrusion 23 which fits into the opening 22 of the PCB 17 increasing a creepage distance. Moreover, as already detailed with regards to FIG. 1, the clearance distance can also be increased by inserting an isolation material between leads or between sets of leads. In FIG. 7 and in FIG. 8, different sets of leads 1 are grouped together, and the opening 22 is inserted in the PCB 17 to divide the sets of leads 1 and to enable the protrusion 23 of the plastic cover to be inserted until a thickness of the PCB 17 is filled out.

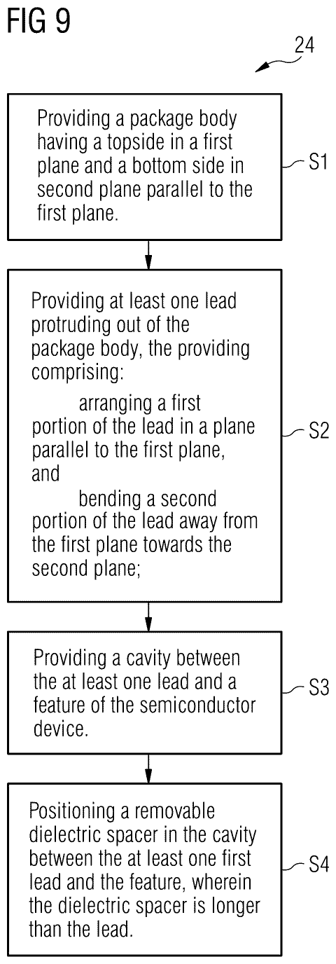

FIG. 9 is a flow diagram of an example method according to the second aspect of the disclosure. The example method is associated with a fabrication method of the semiconductor device 4. As shown in FIG. 9, process 24 includes in a first step S1 providing a package body 2 having a topside in a first plane and a bottom side in second plane parallel to the first plane 9.

As further shown in FIG. 9, in a second step S2, process 24 may include providing at least one lead 1 and protruding out of the package body 2. Providing the at least one lead 1 comprises arranging a first portion of the lead in a plane parallel to the first plane and bending a second portion of the lead away from the first plane towards the second plane.

As further shown in FIG. 9, in a third step S3, process 24 may include providing a cavity between the at least one lead and a feature of the semiconductor device.

As further shown in FIG. 9, in a fourth step S4, process 24 may comprise positioning a removable dielectric spacer in the cavity between the at least one first lead and the feature, wherein the dielectric spacer is longer than the lead.

The foregoing disclosure provides illustration and description but is not intended to be exhaustive or to limit the implementations to the precise forms disclosed. Modifications and variations may be made in light of the above disclosure or may be acquired from practice of the implementations described herein.

Each of the illustrated x-axis, y-axis, and z-axis is substantially perpendicular to the other two axes. In other words, the x-axis is substantially perpendicular to the y axis and the z-axis, the y-axis is substantially perpendicular to the x-axis and the z axis, and the z-axis is substantially perpendicular to the x-axis and the y-axis. In some cases, a single reference number is shown to refer to a surface, or fewer than all instances of a part may be labeled with all surfaces of that part. All instances of the part may include associated surfaces of that part despite not every surface being labeled.

The orientations of the various elements in the figures are shown as examples, and the illustrated examples may be rotated relative to the depicted orientations. The descriptions provided herein, and the claims that follow, pertain to any structures that have the described relationships between various features, regardless of whether the structures are in the particular orientation of the drawings, or are rotated relative to such orientation. Similarly, spatially relative terms, such as “top,” “bottom,” “below,” “beneath,” “lower,” “above,” “upper,” “middle,” “left,” and “right,” are used herein for ease of description to describe one element's relationship to one or more other elements as illustrated in the figures. The spatially relative terms are intended to encompass different orientations of the element, structure, and/or assembly in use or operation in addition to the orientations depicted in the figures. A structure and/or assembly may be otherwise oriented (rotated 90 degrees or at other orientations), and the spatially relative descriptors used herein may be interpreted accordingly. Furthermore, the cross-sectional views in the figures only show features within the planes of the cross-sections, and do not show materials behind the planes of the cross-sections, unless indicated otherwise, in order to simplify the drawings.

As used herein, the terms “substantially” and “approximately” mean “within reasonable tolerances of manufacturing and measurement.” For example, the terms “substantially” and “approximately” may be used herein to account for small manufacturing tolerances or other factors (e.g., within 5%) that are deemed acceptable in the industry without departing from the aspects of the implementations described herein. For example, a resistor with an approximate resistance value may practically have a resistance within 5% of the approximate resistance value. As another example, an approximate signal value may practically have a signal value within 5% of the approximate signal value.

Even though particular combinations of features are recited in the claims and/or disclosed in the specification, these combinations are not intended to limit the disclosure of implementations described herein. Many of these features may be combined in ways not specifically recited in the claims and/or disclosed in the specification. For example, the disclosure includes each dependent claim in a claim set in combination with every other individual claim in that claim set and every combination of multiple claims in that claim set. As used herein, a phrase referring to “at least one of” a list of items refers to any combination of those items, including single members. As an example, “at least one of: a, b, or c” is intended to cover a, b, c, a+b, a+c, b+c, and a+b+c, as well as any combination with multiples of the same element (e.g., a+a, a+a+a, a+a+b, a+a+c, a+b+b, a+c+c, b+b, b+b+b, b+b+c, c+c, and c+c+c, or any other ordering of a, b, and c).

Further, it is to be understood that the disclosure of multiple acts or functions disclosed in the specification or in the claims may not be construed as to be within the specific order. Therefore, the disclosure of multiple acts or functions will not limit these to a particular order unless such acts or functions are not interchangeable for technical reasons. Furthermore, in some implementations, a single act may include or may be broken into multiple sub acts. Such sub acts may be included and part of the disclosure of this single act unless explicitly excluded.

No element, act, or instruction used herein should be construed as critical or essential unless explicitly described as such. Also, as used herein, the articles “a” and “an” are intended to include one or more items and may be used interchangeably with “one or more.” Further, as used herein, the article “the” is intended to include one or more items referenced in connection with the article “the” and may be used interchangeably with “the one or more.” Where only one item is intended, the phrase “only one,” “single,” or similar language is used. Also, as used herein, the terms “has,” “have,” “having,” or the like are intended to be open-ended terms that do not limit an element that they modify (e.g., an element “having” A may also have B). Further, the phrase “based on” is intended to mean “based, at least in part, on” unless explicitly stated otherwise. As used herein, the term “multiple” can be replaced with “a plurality of” and vice versa. Also, as used herein, the term “or” is intended to be inclusive when used in a series and may be used interchangeably with “and/or,” unless explicitly stated otherwise (e.g., if used in combination with “either” or “only one of”).

### LIST OF REFERENCE SIGNS

1 Leads
2 Package body
3 Slot
4 Semiconductor device
5 Dielectric spacer
6 Recesses
7 Edge portion
8 Groove structure
9 First plane
10 Further device
11 Opening
12 First portions of the dielectric spacer
13 Second portions of the dielectric spacer
14 Third portions of the dielectric spacer
15 Heatsink
16 Bottom side of heatsink
17 Substrate/PCB
18 Ground connection
19 Clip
20 Lock-in catch
21 Step
22 Opening of PCB
23 Protrusion
24 Process

What is claimed is:

1. A semiconductor device, comprising:
a package body having a topside in a first plane and a bottom side in a second plane parallel to the first plane,
at least one first lead protruding out of the package body and comprising:
a first portion in a plane parallel to the first plane, and
a second portion being bent away from the first plane towards the second plane;
a cavity positioned between the at least one first lead and a feature of the semiconductor device; and
a removable dielectric spacer configured to be positioned in the cavity between the at least one first lead and the feature,
wherein the dielectric spacer is longer than the at least one first lead.

2. The semiconductor device of claim 1, wherein the feature is a second lead.

3. The semiconductor device of claim 1, wherein the dielectric spacer extends into the cavity.

4. The semiconductor device of claim 1, wherein the dielectric spacer contacts a bottom surface of the cavity.

5. The semiconductor device of claim 1, wherein the dielectric spacer extends along the second portion of the at least one first lead, to encapsulate at least an outer side of the at least one first lead and to fill a clearance distance between neighboring leads.

6. The semiconductor device of claim 1, wherein the feature is a heatsink, and wherein the heatsink comprises a flat bottom surface and is attached to the topside of the package body and protrudes horizontally past a peripheral sidewall of the package body.

7. The semiconductor device of claim 6, wherein an outer edge of the heatsink protrudes past an outer edge of the dielectric spacer, and/or wherein the dielectric spacer does not pass the outer edge of the heatsink.

8. The semiconductor device of claim 6, wherein the dielectric spacer is configured to fill a clearance distance between the second portion of the at least one first lead and the bottom surface of the heatsink.

9. The semiconductor device of claim 1, wherein the dielectric spacer is a plastic cover, wherein the plastic cover is an integral part, and wherein the plastic cover is configured to be removably attachable to the package body by way of a screw or a clip or a latch.

10. The semiconductor device of claim 1, wherein the dielectric spacer acts as a standoff including the second portion of the at least one first lead, and wherein the standoff is configured to control a distance between the bottom side of the package body and a second device to which the semiconductor device is to be attached.

11. The semiconductor device of claim 10, wherein the standoff comprises a protrusion which protrudes into a slot of the second device, and wherein the second device is a printed circuit board (PCB) to enhance a creepage distance between two leads on the PCB.

12. The semiconductor device of claim 11, wherein the protrusion has a height of about a thickness of the PCB.

13. The semiconductor device of claim 11, wherein the slot is a through-hole, through which the protrusion protrudes, and wherein a length of the protrusion is at least a length of the second portion of the at least one first lead protruding through the second device.

14. A method for manufacturing a semiconductor device, the method comprising:
providing a package body having a topside in a first plane and a bottom side in second plane parallel to the first plane;
providing at least one lead protruding out of the package body, the providing comprising:
arranging a first portion of the at least one lead in a plane parallel to the first plane, and
bending a second portion of the at least one lead away from the first plane towards the second plane;
providing a cavity between the at least one lead and a feature of the semiconductor device; and
positioning a removable dielectric spacer in the cavity between the at least one lead and the feature, wherein the dielectric spacer is longer than the at least one lead.
